(19) United States
(12) Patent Application Publication
(10) Pub. No.: US 2025/0089395 A1
(43) Pub. Date: Mar. 13, 2025

(54) PHOTOVOLTAIC CELL PASSIVATION PROCESS

(71) Applicant: COMMISSARIAT A L'ENERGIE ATOMIQUE ET AUX ENERGIES ALTERNATIVES, PARIS (FR)

(72) Inventors: Samuel HARRISON, GRENOBLE CEDEX 09 (FR); Mickaël ALBARIC, GRENOBLE CEDEX 09 (FR); Benoît MARTEL, GRENOBLE CEDEX 09 (FR)

(21) Appl. No.: 18/824,430

(22) Filed: Sep. 4, 2024

(30) Foreign Application Priority Data
Sep. 5, 2023 (FR) 2309303

(51) Int. Cl. H01L 31/18

(52) U.S. Cl. CPC H10F 71/129

(57) ABSTRACT

A method for passivating photovoltaic cells includes providing a plurality of photovoltaic cells, each cell including a front face, a rear face and a peripheral edge connecting the front and rear faces, on each cell, forming an insulation element shaped along the perimeter of the cell, the insulation element being formed on the front or rear face, stacking the plurality of cells, the insulation element being positioned between two adjacent cells so that the face of the cell provided with the insulation element is positioned at a distance from the face facing the adjacent cell, and depositing a passivation layer onto the peripheral edge of the cells by injecting a passivation species, the insulation element forming a penetration barrier to the passivation species so that the passivation layer covers the peripheral edge of the cells.

### TECHNICAL FIELD

The present invention generally relates to the manufacture of photovoltaic cells.

The invention more particularly relates to a method for passivating photovoltaic cells.

### STATE OF THE ART

A photovoltaic module comprises a multitude of identical photovoltaic cells connected in series and/or parallel to output the voltage and/or current required to power electrical devices. The most common module format employs 60 square (or “pseudo-square”) cells, 156 mm on a side, divided into six strings of ten cells connected in series. The six strings of photovoltaic cells are also connected in series. The open-circuit voltage across the module is 60 times the threshold voltage of a photovoltaic cell. The electric current of the module approximately corresponds to the current supplied by each photovoltaic cell (in practice, the photovoltaic cells do not have exactly the same performance and the electric current is limited by the least efficient cell in the module).

With the latest photovoltaic cell technologies, especially PERT (Passivated Emitter and Rear Totally diffused) technology, the current of a 156 mm×156 mm area monofacial cell reaches high values, in the order of 9 A for solar irradiance of 1000 W/m². These current values are increased by around 20% when a bifacial cell is used, due to the diffuse solar radiation captured on the rear face of the cell. This high electric current circulates in interconnection elements between the cells of the module and causes significant resistive losses.

In order to reduce these resistive losses, one solution is to assemble modules with photovoltaic cells with a smaller surface area and therefore a lower current. These cells with a smaller surface area are commonly called “sub-cells” and are obtained by cutting full-size photovoltaic cells (e.g. 156 mm×156 mm).

However, cutting a photovoltaic cell creates new edges which are thereby exposed. Furthermore, cutting (with a laser for example) is likely to create defects and introduce impurities in proximity to the cutting plane. These defects and impurities shorten the life of the free charge carriers by acting as recombination centres for electron-hole pairs, resulting in a reduction in the cell efficiency. This phenomenon is particularly pronounced for heterojunction (HET) photovoltaic cells, which by nature have very few surface defects and where the creation of a few localised defects is sufficient to significantly reduce electrical performance of the cell.

A method for passivating photovoltaic cells for locating the deposition of a passivation material in the vicinity of one edge only of the photovoltaic cell is especially known from document FR3091025.

In order to be compatible with the industrial production requirements, while depositing a passivation material only onto the edges of the photovoltaic cells, document FR3091025 describes an arrangement consisting in stacking a plurality of photovoltaic cells on top of each other, the stack directly resting on a support.

According to this arrangement, the front and rear faces of each photovoltaic cell are therefore in direct contact with one of the faces of another photovoltaic cell or with the support. This direct contact leads to risks of degradation of these front and rear faces, resulting in degraded electrical performance (in particular of the final photovoltaic modules comprising these photovoltaic cells).

### SUMMARY OF THE INVENTION

The present invention therefore aims to improve manufacture of photovoltaic cells by ensuring especially that the photovoltaic cell passivation process does not degrade the photovoltaic cells themselves or the electrical performance associated therewith, whether the photovoltaic cells are considered independently of one another or interconnected in a photovoltaic module.

The invention then firstly relates to a method for passivating photovoltaic cells comprising the steps of:
providing a plurality of photovoltaic cells, each photovoltaic cell comprising a front face, to be exposed to incident radiation, a rear face opposite to the front face and a peripheral edge connecting the front face and the rear face,
on each photovoltaic cell of the plurality of photovoltaic cells, forming a first insulation element shaped along the perimeter of the photovoltaic cell concerned, the first insulation element being formed on the front face or on the rear face of the photovoltaic cell concerned,
stacking the plurality of photovoltaic cells, the first insulation element of each photovoltaic cell being positioned between the photovoltaic cell concerned and an adjacent photovoltaic cell in such a way that the face of the photovoltaic cell provided with the first insulation element is positioned at a distance from the face facing the adjacent photovoltaic cell, and
depositing a passivation layer onto the peripheral edge of the photovoltaic cells of the plurality of photovoltaic cells by injecting at least one passivation species, the first insulation element forming a penetration barrier to the passivation species so that the passivation layer covers the peripheral edge of each photovoltaic cell.

Thus, advantageously according to the invention, the use of the insulation element makes it possible to stack the photovoltaic cells without the front and rear faces of each photovoltaic cell being subjected to stresses at the metallisations. This prevents degradations in electrical performance and limits mechanical breakage of the photovoltaic cells.

Furthermore, by virtue of the presence of the insulation element, when the photovoltaic cells are stacked, only the peripheral edge of each photovoltaic cell is visible and accessible from outside the stack. In other words, the insulation element insulates the front and rear faces of each photovoltaic cell from outside the stack. This then ensures that only the peripheral edge of the photovoltaic cells is exposed to the passivating species for the deposition of the passivating layer (the other parts of the photovoltaic cells being insulated by virtue of the presence of insulation elements between each photovoltaic cell, which form a barrier to the passivating species used).

Locating the deposition only on the peripheral edge (and not on all the faces of each photovoltaic cell) facilitates the subsequent interconnection step of the photovoltaic cells. This avoids degrading electrical performance of the photovoltaic cells.

Further to the characteristics just discussed in the previous paragraphs, the passivation method in accordance with the invention may have one or more additional characteristics from among the following, considered individually or according to any technically possible combinations:
for each photovoltaic cell of the plurality of photovoltaic cells, the first insulation element is preferably formed, on one of the front face or the rear face, at a distance, from the peripheral edge, of less than 50 micrometres;
the first insulation element has a width of less than 100 micrometres;
the first insulation element has a width comprised between 30 and 60 micrometres;
each photovoltaic cell having, on at least one of the front face and the rear face, at least one metallisation element, the first insulation element has a height greater than or equal to the height of the metallisation element;
the first insulation element is formed of an electrically conductive metal material;
the first insulation element is formed by screen printing;
the first insulation element is formed of a polymeric material;
during the stacking step, the photovoltaic cells are positioned in such a way that the first insulation element formed is in direct contact with one of the faces of the adjacent photovoltaic cell;
for each photovoltaic cell, there is provided a step of forming a second insulation element shaped along the perimeter of the photovoltaic cell concerned, the second insulation element being formed on the same face as the first insulation element, in parallel with the first insulation element;
the second insulation element is formed at a distance from the first insulation element of less than 50 micrometres;
for each photovoltaic cell, there is provided a step of forming a third insulation element shaped along the perimeter of the photovoltaic cell concerned, the third insulation element being formed on the face opposite to the face provided with the first insulation element;
during the stacking step, the photovoltaic cells are positioned so that the third insulation element of a photovoltaic cell is placed between the first insulation element and the second insulation element of the adjacent photovoltaic cell, the third insulation element being in direct contact with the face of the adjacent photovoltaic cell on which the first insulation element and the second insulation element are formed;
for each photovoltaic cell, there is provided a step of forming a fourth insulation element shaped along the perimeter of the photovoltaic cell concerned, the fourth insulation element being formed on the face opposite to the face provided with the first insulation element, the fourth insulation element being formed facing the first insulation element; and
in the stacking step, the photovoltaic cells are positioned so that the first insulation element of one photovoltaic cell is in contact with the fourth insulation element of the adjacent photovoltaic cell.

### BRIEF DESCRIPTION OF THE FIGURES

Further characteristics and advantages of the invention will be more apparent from the description thereof given below, by way of indicating and in no way limiting purposes, with reference to the appended figures, in which:

FIG. 1 is a top view of a photovoltaic cell according to a first embodiment of a passivation method in accordance with the invention,

FIG. 2 is a cross-section view of a stack comprising the photovoltaic cell of FIG. 1,

FIG. 3 is a top view of a photovoltaic cell according to a second embodiment of the passivation method in accordance with the invention,

FIG. 4 is a cross-section view of a stack comprising the photovoltaic cell of FIG. 3,

FIG. 5 represents a cross-section view of a photovoltaic cell according to a third embodiment of the passivation method in accordance with the invention,

FIG. 6 is a cross-section view of a stack comprising the photovoltaic cell of FIG. 5,

FIG. 7 represents a cross-section view of a photovoltaic cell according to a fourth embodiment of the passivation method in accordance with the invention,

FIG. 8 is a cross-section view of a stack comprising the photovoltaic cell of FIG. 7,

FIG. 9 represents a cross-section view of a photovoltaic cell according to a fifth embodiment of the passivation method in accordance with the invention,

FIG. 10 is a cross-section view of a stack comprising the photovoltaic cell of FIG. 9.

For greater clarity, identical or similar elements are marked with identical reference signs throughout the figures.

### DETAILED DESCRIPTION OF AT LEAST ONE EMBODIMENT

The present invention aims at improving the manufacturing of photovoltaic cells and in particular at improving the passivation phase of photovoltaic cells. It is aimed especially at limiting deposition of thin layers onto the side trenches of photovoltaic cells.

The photovoltaic cells 5 relating to the present invention are, for example, full-size cells or sub-cells, i.e. portions or pieces of a full-size photovoltaic cell (also referred to as a “whole” photovoltaic cell).

The sub-cells are, for example, previously obtained by cutting full-size photovoltaic cells.

The full-size photovoltaic cells have previously been manufactured from semiconductor substrates, for example of crystalline silicon. These substrates have initially been cut from a silicon ingot, and then subjected to a number of manufacturing steps (e.g. surface structuring, doping, annealing, passivation, screen printing steps etc.), but no further cutting steps. Full-size photovoltaic cells have passivation layers on all of their faces and side surfaces.

The photovoltaic cells 5 related to the present invention each comprise a first face 5A and a second face 5B, opposite to the first face 5A. The first face 5A is, for example, the one to be exposed to the incident solar radiation. In this case, the first face 5A corresponds to the front face 5A of the photovoltaic cell 5 concerned. The rest of this description is based on this example, considering, for each photovoltaic cell 5, the front face 5A (exposed to the incident solar radiation) and the rear face 5B (opposite to the front face 5A).

Each photovoltaic cell 5 also comprises a peripheral edge 5C connecting the front face 5A and the rear face 5B. This peripheral edge 5C thus corresponds to the side surface connecting the front face 5A and the rear face 5B. By definition here, the peripheral edge 5C therefore extends over the entire perimeter of the front face 5A and rear face 5B of the photovoltaic cell 5. In this description, by “perimeter” of the photovoltaic cell 5, it is meant the contour line of the front face 5A and/or rear face 5B.

When viewed from the front (from the front face 5A or the rear face 5B), the photovoltaic cells 5 preferably have a rectangular or pseudo-rectangular shape. In the pseudo-rectangular format, the four corners of the photovoltaic cells 5 are truncated or rounded. In particular, the photovoltaic cells 5 may have a square or pseudo-square shape.

The perimeter of the photovoltaic cell 5 thus has a rectangular or pseudo-rectangular shape (or, in the particular case, a square or pseudo-square shape).

The dimensions of the front face 5A and rear face 5B are generally standardised, for example 156 mm×156 mm. In the case of sub-cells (resulting from the cutting of a full-size photovoltaic cell), these dimensions are, for example, in the order of 156 mm×78 mm.

The photovoltaic cells 5 may be monofacial or bifacial cells. In the case of a monofacial cell, only the front face 5A of the photovoltaic cell 5 captures solar radiation. In the case of a bifacial cell, both faces 5A, 5B of the photovoltaic cell 5 capture solar radiation. The front face 5A is then the one that allows the maximum electric current to be obtained when it is pointing towards the sun.

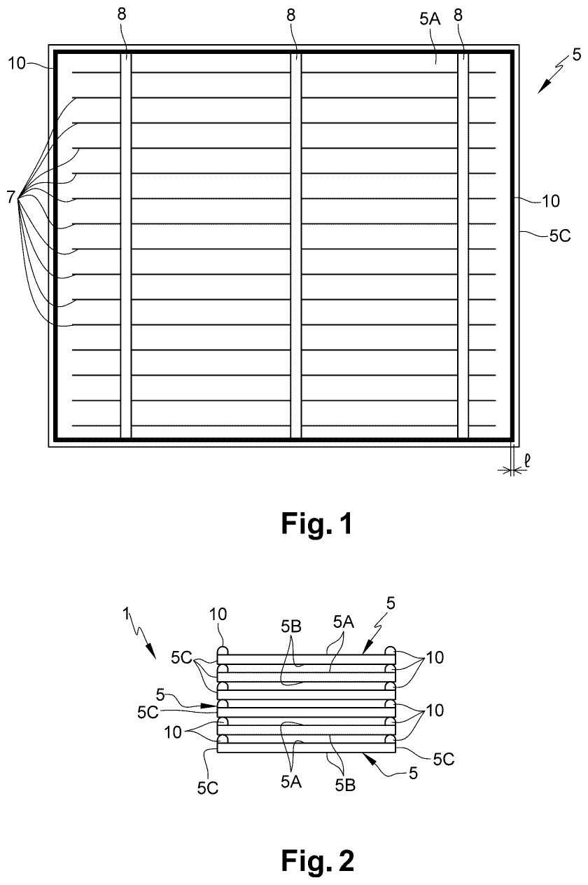

Preferably, the photovoltaic cells 5 are ready to be interconnected into a string of cells. They are provided on the front face 5A and/or on the rear face 5B with one or more metallisation elements 7, 8 (also referred to hereinafter as “metallisations 7, 8”) for collecting the photogenerated charge carriers and receiving interconnection elements, for example metal wires or ribbons. The metallisations 7, 8 are represented here only in FIG. 1 but are present on all the photovoltaic cells 5 used in the present invention.

The metallisations 7, 8 are preferably here an array of electrodes 7 (also called “collection fingers 7”) and electrically conductive interconnection tracks 8 called “busbars 8”. The busbars 8 can electrically connect collection fingers 7 distributed over the entire surface area of the front face 5A and/or rear face 5B. The rear face 5B of the photovoltaic cells 5 may also be entirely metallised.

The electrodes forming the collection fingers 7 are for example deposited onto the front face 5A of the photovoltaic cell 5. These collection fingers 7 generally extend in parallel to one another along the front face 5A of each photovoltaic cell 5. They are here preferably uniformly distributed over the front face 5A of each photovoltaic cell 5.

The collection fingers 7 are narrow, i.e. they have a width of less than 100 micrometres (μm), for example. The width is preferably less than 50 μm. Their height is in the order of a few tens of micrometres. Preferably, this height is less than 30 μm. Preferably, this height is between 10 and 20 μm.

They are generally formed by screen printing a paste containing silver or copper. Alternatively, they can be formed by deposition by inkjet printing or by plating.

The rear face 5B of the photovoltaic cell 5 is either covered with another electrode array (in the case of bifacial cells), or with a solid metal layer, for example of aluminium (in the case of monofacial cells).

In order to transport electric current in a photovoltaic string comprising several interconnected photovoltaic cells, the collecting fingers 7 are connected together by busbars 8. These busbars 8 are generally formed at the same time as the collection fingers 7. The busbars 8 are also formed, for example, by screen-printing a paste containing silver or copper. Alternatively, they may be formed by inkjet deposition or plating.

As is visible for example in FIG. 1, the busbars 8 electrically connect the collection fingers 7 and are oriented perpendicularly to the collection fingers 7. The photovoltaic cell 5 represented schematically in FIG. 1 here comprises three busbars 8, extending perpendicularly to the plurality of collection fingers 7 represented. Preferably, each photovoltaic cell comprises between 6 and 10 busbars.

Each busbar 8 has a width greater than or equal to the width of each collection finger 7. The width of each busbar is, for example, less than a few hundred micrometres, for example less than 500 μm. Preferably, the width of each busbar 8 is between 50 and 300 μm.

Each busbar 8 has a height greater than or equal to the height of each collection finger 7. The height of each busbar 8 is less than 50 μm. Preferably, it is between 20 and 30 μm.

In one alternative implementation (not represented), the photovoltaic cells may have no busbars but include only collection fingers.

As the photovoltaic cells 5 are obtained, for example, by cutting a full-size photovoltaic cell whose faces are provided with passivation layers, the front face 5A and the rear face 5B of each photovoltaic cell 5 have a passivation layer. This passivation layer makes the surface defects of the photovoltaic cell 5 inactive and improves lifetime of the photogenerated charge carriers.

On the other hand, the peripheral edge 5C of the photovoltaic cell comprises zones where the semiconductor material (i.e. the silicon) has been exposed. In other words, these zones of the peripheral edge 5C are devoid of a passivation layer (due to the cutting), unlike the front face 5A, the rear face 5B and the (possible) other zones of the peripheral edge 5C of the photovoltaic cell 5. For example, when a full-size photovoltaic cell is cut into four parallel cell strips, two cell strips have two unpassivated parallel edges, and two other cell strips have a single unpassivated edge.

The photovoltaic cells 5 concerned may also be full-size cells in which part of the peripheral edge 5C has been abraded. This is the case, for example, when a junction opening is implemented to prevent possible short circuits. In this case, the peripheral edge 5C of the photovoltaic cell 5 also has a non-passivated part on its peripheral edge 5C.

The present invention therefore aims to protect, by forming a passivation layer, these zones in which the semiconductor material is exposed, without this deposition reaching the front face 5A and the rear face 5B of each photovoltaic cell 5 (as this would risk degrading electrical performance of the photovoltaic cell 5).

For this, the present invention relates to a method for passivating photovoltaic cells 5 so as to form a passivation layer on part of each of the photovoltaic cells 5.

FIGS. 1 to 10 are associated with different embodiments of this passivation method in accordance with the invention.

It is to be noted that, prior to implementation of the passivation method (whatever the embodiment considered), the photovoltaic cells 5 have been manufactured from semiconductor substrates (of crystalline silicon, for example). They have also, for example, been cut or subjected to abrasion of part of their peripheral edge after the full-size photovoltaic cells have been manufactured.

FIGS. 1 and 2 show the first example implementation of the passivation method.

This method comprises a first step of providing a plurality of photovoltaic cells 5. In this step, all the photovoltaic cells 5 of the plurality of photovoltaic cells considered have the same shape and the same dimensions.

The method then continues with a second step of forming an insulation element 10 on each photovoltaic cell 5 of the plurality of photovoltaic cells provided. For the sake of clarity, this second step is described in connection with one photovoltaic cell 5 of the plurality of photovoltaic cells provided in the first step but applies equally to all photovoltaic cells of that plurality.

According to the first embodiment of the passivation method, the insulation element 10 is formed on one of the faces 5A, 5B of the photovoltaic cell 5. In FIGS. 1 and 2, the insulation element 10 is formed here on the front face 5A of the photovoltaic cell 5. Alternatively, the insulation element can of course be formed, in the same way, on the rear face of the photovoltaic cell. It is to be noted here that this insulation element 10 is distinct from the metallisation elements 7, 8 already present on one or both faces 5A, 5B of the photovoltaic cell 5. In particular, the insulation element 10 is distinct from possible busbars present on the photovoltaic cell 5.

Advantageously, as is visible in FIG. 1, the insulation element 10 is shaped along the perimeter of the photovoltaic cell 5. In other words, the insulation element 10 has the shape of the circumference (i.e. the outer boundary) of the photovoltaic cell 5.

Here, given that the photovoltaic cell 5 has a rectangular shape, the insulation element 10 therefore extends in a rectangular shape corresponding to the periphery of the photovoltaic cell 5 (as is visible in FIG. 1).

In practice, the insulation element 10 is formed (here on the front face 5A of the photovoltaic cell 5) in proximity to the peripheral edge 5C. More particularly, the insulation element 10 is preferably formed at a distance of less than 50 μm from the peripheral edge 5C (thus from the edge of the front face 5A of the photovoltaic cell 5).

The insulation element 10 here has a width l of less than 100 μm. In this description, by “width of the insulation element”, it is meant the dimension in a transverse direction of the insulation element 10. Preferably, this width l is between 30 and 60 μm. The formation of the thinnest possible insulation element makes it possible to limit induced parasitic shading, i.e. the shadow formed due to the presence of the insulation element 10, on the photovoltaic cell 5 (too great a shadow would reduce the final electrical production of the photovoltaic string comprising the plurality of photovoltaic cells connected together).

Furthermore, the height of the insulation element 10 is here greater than or equal to the height of the metallisations 7, 8 present on the front face 5A of the photovoltaic cell 5. In this description, the “height” of the insulation element 10 corresponds to the dimension of the insulation element 10 in a direction orthogonal to the front face 5A of the photovoltaic cell 5. This condition on the height of the insulation element 10 makes it possible to avoid degrading the metallisations 7, 8 when the photovoltaic cells 5 are stacked on top of each other (as described hereinafter).

In practice, the height of the insulation element 10 is greater than or equal to the height of the busbars 8 (which are generally the metallisation elements formed on the face of the photovoltaic cell that have the greatest height). For example, the height of the insulation element 10 is less than 150 μm. Preferably, the height of the insulation element 10 is between 50 and 130 μm.

The insulation element 10 is for example in the form of a cord extending along the perimeter of the photovoltaic cell 5. This cord comprises for example a rectangular or cylindrical transverse cross-section. Alternatively, the transverse cross-section of the insulation element may be of any shape.

According to a first example, the insulation element 10 is formed of an electrically conductive metal material. Advantageously in this case, if the insulation element 10 is electrically connected to the metallisation elements 7, 8, this makes it possible to enhance the overall contact in the event of a line break.

In this first example, the insulation element 10 is for example formed by screen-printing a paste containing silver or copper. In this case, for the sake of efficiency and simplification, the insulation element 10 is for example deposited at the same time as the metallisation elements 7, 8 of the photovoltaic cell 5. Alternatively, it may be formed after manufacturing the metallisation elements 7, 8.

Alternatively, the insulation element 10 may be formed by deposition by inkjet printing or by plating. In these cases, the insulation element may be formed simultaneously with or after the formation of the metallisation elements 7, 8.

According to a second example, the insulation element 10 is formed of an electrically non-conductive material. Any type of material may be contemplated.

Preferably, in this second example, the insulation element 10 is formed of a polymeric material. These include rubber derivatives, for example. The following commercial products may be used: PETERS SD 2052, MICROMAX® 5018 or MICROMAX® 5036.

Examples are hard polymeric materials or soft polymeric materials. A soft polymeric material is defined, for example, on the basis of the standard Shore A hardness scale. Within the scope of the invention, materials under consideration have, for example, an index of between 70 and 90 on this Shore A scale. They are, for example, fluoroelastomers.

In particular, the use of soft polymeric material makes it possible to obtain a transparent insulation element, thus limiting parasitic shading induced on the photovoltaic cell. By transparent in this description, it is meant an element which allows more than 70% of the incident radiation, and preferably at least 80% of the incident radiation, to pass in the visible spectrum. For example, they are polymers of the PEDOT: PSS type (formed of a mixture of two polymers, poly(3,4-ethylenedioxythiophene) (PEDOT) and sodium poly(styrene sulphonate) (PSS)).

The use of soft polymeric materials improves efficiency of the joint between the insulation element and the adjacent photovoltaic cell when stacking the plurality of photovoltaic cells (as described hereinafter).

Alternatively, the insulation element may be formed of a resin. This resin is, for example, polyamide, acetonitrile butadiene styrene or polyester.

Finally, in this first embodiment, at the end of the second step of the passivation method, each photovoltaic cell 5 of the plurality of photovoltaic cells is provided with an insulation element 10 formed on one of the front face 5A or the rear face 5B (herein, as represented in FIG. 2, the insulation element 10 is formed on the front face 5A of each photovoltaic cell 5).

The passivation method then continues with a third step of stacking the plurality of photovoltaic cells 5 each provided with its insulation element 10 (a stack 1, visible in FIG. 2, of photovoltaic cells and insulation elements 10 is thus formed).

In this description, by “stacking” photovoltaic cells, it is meant the arrangement of these photovoltaic cells one after the other. A group of photovoltaic cells 5 is thus formed.

This stack 1 is for example implemented vertically: the photovoltaic cells 5 are then superimposed on one another (as is represented in FIG. 2). Alternatively, the stack may be made horizontally. In this case, the photovoltaic cells are positioned one after the other (they are juxtaposed).

In practice, this stack is for example implemented on a support (not represented) to be positioned subsequently in a thin film deposition chamber (for the corresponding step described hereinafter).

Advantageously according to the invention, each photovoltaic cell 5 is positioned so that the insulation element 10 of the photovoltaic cell 5 concerned is placed between this photovoltaic cell 5 and the adjacent photovoltaic cell 5. In other words, in the stack 1, the photovoltaic cells 5 are arranged one after the other with the positioning of an insulation element 10 between two adjacent photovoltaic cells 5. This arrangement is implemented in such a way that the front face 5A of the photovoltaic cell 5 provided with the insulation element 10 is positioned at a distance from the rear face 5B of the adjacent photovoltaic cell 5. For the record, the photovoltaic cells 5 considered in this first embodiment all have the same configuration with an insulation element formed on their front face 5A. The faces of the photovoltaic cells 5 are therefore not in contact with each other when they are stacked. This makes it possible especially to avoid degrading the metallisation elements, and therefore electrical performance of the photovoltaic cells.

In this stacking step, the insulation element 10 (of a photovoltaic cell 5) is therefore positioned in direct contact with the rear face 5B of the adjacent photovoltaic cell 5.

This configuration is particularly advantageous because it enables the photovoltaic cells 5 to be stacked without the front and rear faces of each photovoltaic cell 5 being subjected to stresses at the metallisations. This prevents degradations in electrical performance.

Furthermore, by virtue of the presence of the insulation element 10, when the photovoltaic cells 5 are stacked, only the peripheral edge 5C of each photovoltaic cell 5 is visible and accessible from outside the stack 1. In other words, the insulation element 10 insulates the front face 5A and the rear face 5B of each photovoltaic cell 5 from outside the stack 1. This then ensures that only the peripheral edge 5C of the photovoltaic cells 5 is exposed to at least one passivation species for the deposition of the passivation layer as described hereinafter (the other parts of the photovoltaic cells 5 being insulated by virtue of the presence of the insulation elements between each photovoltaic cell 5, which form a barrier to the passivation species used).

The passivation method then comprises a step of depositing a passivation layer onto a part of the photovoltaic cells 5 stacked. For this, the stack 1 of photovoltaic cells 5 is placed, for example, in a thin film deposition chamber (not represented in the figures). The passivation layer is formed from at least one passivation species. Preferably, this passivation species is in the form of a gas. The passivation layer is then deposited by injecting the passivation species into the aforementioned deposition chamber.

In practice, a passivation layer is formed, for example, by Atomic Layer Deposition (ALD). According to this method, different precursor gases are introduced into the thin film deposition chamber and conveyed to the different zones (here the peripheral edge 5C of each photovoltaic cell 5) onto which one or more atomic layers are to be deposited.

An atomic layer is formed on a zone concerned (i.e. here the peripheral edge 5C of each photovoltaic cell 5) by exposing this zone to the flow of a first precursor gas injected into the thin film deposition chamber by injection means (not represented). This first precursor gas reacts with the terminals of the zone concerned and forms a single layer containing other terminals (reactive groups). A second precursor gas (also injected by the injection means) then introduced reacts with the terminals of the single layer formed (following injection of the first precursor gas) so as to form the desired passivation layer.

In practice, the injection means are for example formed by an injection head (not represented) allowing the gas to be introduced into the thin film deposition chamber. The deposition conditions (such as the position of the injection head, the gas flow rates, the concentration of the precursors and the temperature) and the dimensions of the injection head are advantageously chosen so that the passivation layer is formed at the peripheral edge 5C of each photovoltaic cell 5 of the stack 1.

Preferably, the material of the passivation layer is, for example, alumina (Al₂O3), silicon dioxide (SiO₂), silicon nitride (Si₃N₄) or hydrogenated amorphous silicon (a-Siₓ:H).

The thickness of the passivation layer is in the order of a few nanometres (nm) to a few tens of nanometres. For example, in the case of alumina, the thickness of the passivation layer is greater than 5 nm, preferably between 5 and 15 nm. In the case of hydrogenated amorphous silicon, the thickness of the passivation layer is preferably between 5 and 15 nm.

Alternatively, the passivation species may be in the form of a sprayed liquid solution. This is, for example, a sprayed liquid polymer solution. Here the polymer is a fluoropolymer such as Nafion™.

By virtue of the arrangement previously described (formation of an insulation element 10 on the front face 5A of each photovoltaic cell 5 and stacking of the photovoltaic cells 5 one after the other with positioning an insulation element 10 between two adjacent photovoltaic cells 5), only the peripheral edge 5C of each photovoltaic cell 5 is exposed to the passivation species injected into the thin film deposition enclosure. Thus, advantageously, the insulation elements 10 form a barrier preventing penetration of the passivation species so that the passivation layer is formed only on the peripheral edge 5C of each photovoltaic cell 5 of the stack 1 (when the passivation species injected into the thin film deposition chamber is flush with the peripheral edge 5C of each photovoltaic cell 5). In particular, locating the deposition only on the peripheral edge (and not on all the faces of each photovoltaic cell) makes it easier to subsequently interconnect the photovoltaic cells. This avoids degrading electrical performance of the photovoltaic cells. In addition, locating the deposition only on the peripheral edge of each photovoltaic cell makes it possible to avoid degrading the absorption of incident photons (deposition on the faces of each photovoltaic cell leads to parasitic absorption in the optical spectrum concerned and degrades reflection properties of the photovoltaic cell).

Alternatively, the passivation layer can be deposited by other methods. For example, Physical Vapour Deposition (PVD) or Chemical Vapour Deposition (CVD) methods may be used.

Still alternatively, a chemical liquid phase deposition method may be used.

Still alternatively, plasma-based deposition methods may also be used. In such a case, the materials used, in particular for the support parts, should be adapted to be conductive. Graphite can especially be used for this purpose.

In practice, the two photovoltaic cells at the end of the stack are not used subsequently because they are either in direct contact with the support for the deposition of the passivation layer, or are subject to the formation of the passivation layer on the whole of one of its faces. These two photovoltaic cells are in a way sacrificed in the passivation process.

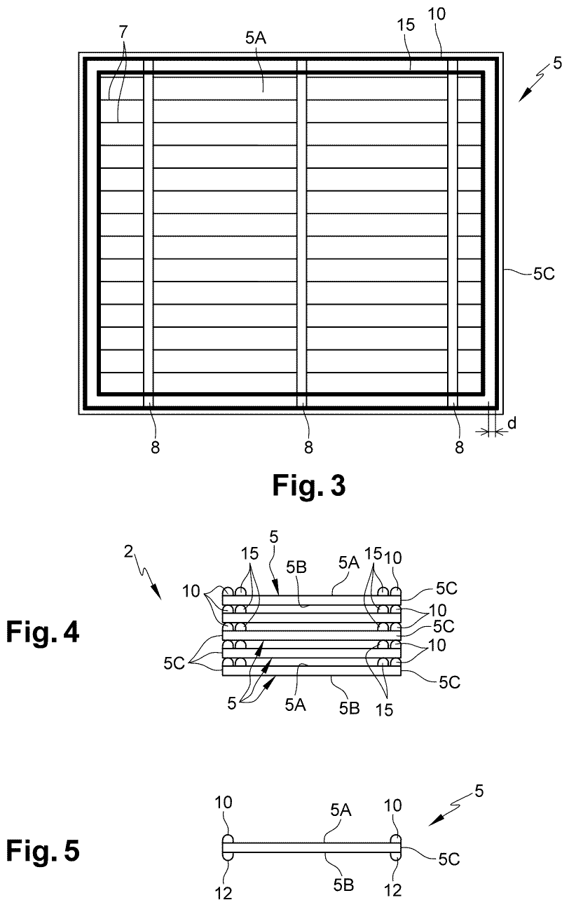

FIGS. 3 and 4 show a second example implementation of the passivation method in accordance with the invention.

The passivation method according to this second example comprises the same steps of providing the plurality of photovoltaic cells 5, forming the insulation element 10, stacking and depositing a passivation layer as the first embodiment previously described. Therefore, only the differences with respect to this first exemplary embodiment are described in detail hereinafter.

In this second embodiment of the passivation method, prior to the stacking step, the passivation method comprises a step of forming another insulation element 15 (on each photovoltaic cell 5 of the plurality of photovoltaic cells).

As is visible in FIGS. 3 and 4, this other insulation element 15 is formed on the same face as the insulation element 10 previously described. Here, therefore, the other insulation element 15 is formed on the front face 5A of each photovoltaic cell 5. Alternatively, if the insulation element is formed on the rear face of the photovoltaic cell, the further insulation element is of course formed, in the same manner, on the rear face of the photovoltaic cell.

Here, as is visible in FIG. 3, the other insulation element 15 is shaped along the perimeter of the photovoltaic cell 5. It is therefore, in practice, shaped along the insulation element 10 already formed. In other words, the other insulation element 15 has the same shape as the insulation element 10.

Here, given that the photovoltaic cell 5 (and the insulation element 10) has a rectangular shape, the other insulation element 15 therefore extends in a rectangular shape corresponding to the periphery of the photovoltaic cell 5 (as is visible in FIG. 3).

In practice, the other insulation element 15 is formed at a distance from the insulation element 10 (thus also at a distance from the peripheral edge 5C of the photovoltaic cell 5). The distance d between the insulation element 10 and the other insulation element 15 is less than 100 μm. Preferably, this distance d is less than 50 μm.

For example, the other insulation element 15 is formed at a distance from the insulation element 10 in the order of the width of this insulation element 10.

For a width of the insulation element 10 in the order of 50 μm, the other insulation element 15 is therefore formed at a distance of less than 150 μm from the peripheral edge 5C (thus from the edge of the front face 5A of the photovoltaic cell 5).

Furthermore, as is represented in FIG. 3, the insulation element 10 and the other insulation element 15 extend in parallel.

For the rest, the other insulation element 15 has the same characteristics as those previously described for the insulation element 10 (in particular as regards the dimensions of width and height, the shape of the transverse cross-section, or the materials used).

It is to be noted that the materials used to form the insulation element 10 and the other insulation element 15 may be different.

Furthermore, in this second mode of implementation of the passivation method, there is no order of formation between the insulation element 10 and the other insulation element 15: either may be formed first in any manner. In particular, they can be formed simultaneously in order to simplify manufacture.

Thus, in this second embodiment, before the stacking step, each photovoltaic cell 5 of the plurality of photovoltaic cells is provided with an insulation element 10 and another insulation element 15, both formed on one of the front face 5A or the rear face 5B (herein, as is represented in FIG. 3, the insulation element 10 and the other insulation element 15 are formed on the front face 5A of each photovoltaic cell 5). For example, the insulation element 10 forms an external insulation element 10 (as it is closest to the edge of the photovoltaic cell 5) and the other insulation element 15 forms an internal insulation element 15 (relative to its “more internal” positioning on the face of the photovoltaic cell 5).

The passivation method then continues with the step of stacking the plurality of photovoltaic cells 5 each provided with the insulation element 10 and the other insulation element 15 (a stack 2, visible in FIG. 4, of photovoltaic cells, insulation elements 10 and other insulation elements 15 is thus formed).

This stack 2 is here implemented vertically: the photovoltaic cells 5 are then superimposed on one another (as is represented in FIG. 4). Alternatively, the stack may be made horizontally. In this case, the photovoltaic cells are positioned one after the other.

Advantageously according to the invention, each photovoltaic cell 5 is positioned so that the insulation element 10 and the other insulation element 15 of the photovoltaic cell 5 concerned are placed between this photovoltaic cell 5 and the adjacent photovoltaic cell 5. In other words, in the stack 2, the photovoltaic cells 5 are arranged one after the other with the positioning of an insulation element 10 and another insulation element 15 between two adjacent photovoltaic cells 5.

This arrangement is implemented in such a way that the front face 5A of the photovoltaic cell 5 provided with the insulation element 10 and the other insulation element 15 is positioned at a distance from the rear face 5B of the adjacent photovoltaic cell 5. For the record, the photovoltaic cells 5 considered in this second embodiment all have the same configuration with an insulation element 10 and another insulation element 15 formed on their front face 5A. The faces of the photovoltaic cells 5 are therefore not in contact with each other when they are stacked. This makes it possible especially to avoid degrading metallisation elements, and therefore electrical performance of the photovoltaic cells.

In this stacking step, the insulation element 10 and the other insulation element 15 (of a photovoltaic cell 5) are therefore positioned in direct contact with the rear face 5B of the adjacent photovoltaic cell 5.

In addition to the advantages set forth for the first embodiment, the configuration of the second embodiment is particularly advantageous because, by virtue of the presence of the other insulation element, it makes it possible to enhance the penetration barrier effect of the passivation species used for depositing the thin film. The insulation element 10 and the other insulation element 15 therefore form a double barrier enabling the front face 5A and the rear face 5B of each photovoltaic cell 5 to be insulated from outside the stack 2. This further ensures that only the peripheral edge 5C of the photovoltaic cells 5 is exposed to the passivation species for the deposition of the passivation layer (the other parts of the photovoltaic cells 5 being insulated by virtue of the presence of the insulation elements and other insulation elements between each photovoltaic cell 5, which form a double barrier to the passivation species used).

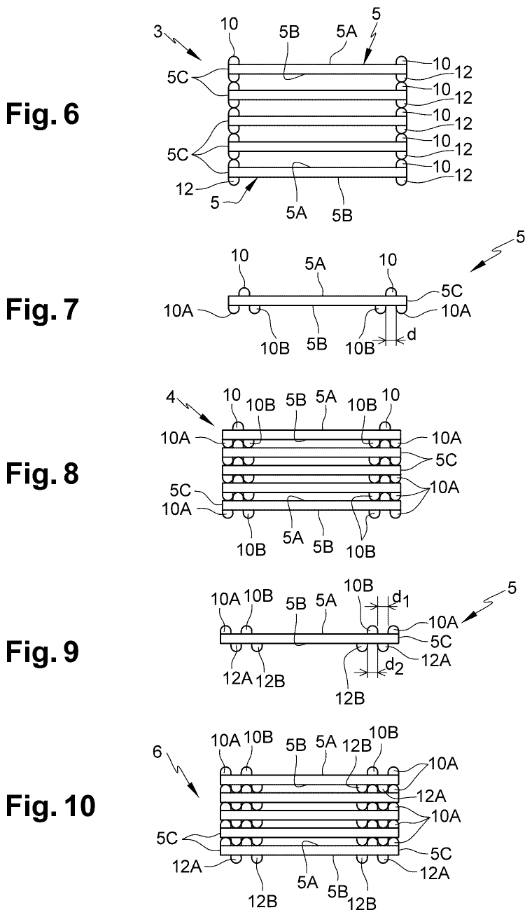

FIGS. 5 and 6 correspond to a third example implementation of the passivation method in accordance with the invention.

The passivation method according to this third example comprises the same steps of providing the plurality of photovoltaic cells, forming the insulation element, stacking and depositing a passivation layer as the first embodiment previously described. Therefore, only the differences with respect to this first exemplary embodiment are described in detail hereinafter.

In this third embodiment of the passivation method, prior to the stacking step, the passivation method comprises a step of forming another insulation element 12 (on each photovoltaic cell 5 of the plurality of photovoltaic cells).

As is visible in FIGS. 5 and 6, this other insulation element 12 is formed on the face opposite to that on which the insulation element 10 described according to the first embodiment is formed. Here, the other insulation element 12 is therefore formed on the rear face 5B of each photovoltaic cell 5. Alternatively, if the insulation element is formed on the rear face of the photovoltaic cell, the other insulation element is of course formed, in the same way, on the front face of the photovoltaic cell.

The other insulation element 12 is formed, on the rear face of the photovoltaic cell 5, in the same way as the insulation element 10 is formed on the front face 5A (as previously described).

Thus, the other insulation element 12 is shaped along the perimeter of the photovoltaic cell 5. In other words, the other insulation element 12 has the shape of the circumference (i.e. the external boundary) of the photovoltaic cell 5.

It is therefore, in practice, shaped according to the already formed insulation element 10. In other words, the other insulation element 12 has the same shape as the insulation element 10.

Here, given that the photovoltaic cell 5 (and the insulation element 10) has a rectangular shape, the other insulation element 12 therefore extends in a rectangular shape corresponding to the periphery of the photovoltaic cell 5.

In practice, as is described for the insulation element 10, the other insulation element 12 is formed (here on the rear face 5B of the photovoltaic cell 5) in proximity to the peripheral edge 5C. More particularly, the other insulation element 12 is formed at a distance of less than 50 μm from the peripheral edge 5C (thus from the edge of the rear face 5B of the photovoltaic cell 5). In other words, the other insulation element 12 is formed facing the insulation element 10.

For the rest, the other insulation element 12 has the same characteristics as those previously described for the insulation element 10 (in particular as regards the width and height dimensions, the shape of the transverse cross-section or the materials used).

It is to be noted that the materials used to form the insulation element 10 and the other insulation element 12 may be different.

Furthermore, in this third mode of implementation of the passivation method, there is no order of formation between the insulation element 10 and the other insulation element 12: either may be formed first indifferently. In particular, they can be formed simultaneously in order to simplify manufacture.

Thus, in this third embodiment, before the stacking step, each photovoltaic cell 5 of the plurality of photovoltaic cells is provided with an insulation element 10 and another insulation element 12, each being formed on different faces of the photovoltaic cell 5 (herein, as represented in FIGS. 5 and 6, the insulation element 10 is formed on the front face 5A of each photovoltaic cell 5 and the other insulation element 12 is formed on the rear face 5B of each photovoltaic cell 5).

The passivation method then continues with the step of stacking the plurality of photovoltaic cells 5 each provided with the insulation element 10 and the other insulation element 12 (a stack 3, visible in FIG. 6, of photovoltaic cells 5, insulation elements 10 and other insulation elements 12 is thus formed).

This stack 3 is here implemented vertically: the photovoltaic cells 5 are then superimposed on one another (as is represented in FIG. 6). Alternatively, the stack may be made horizontally. In this case, the photovoltaic cells are positioned one after the other.

Advantageously according to the invention, each photovoltaic cell 5 is positioned so that the insulation element 10 of the photovoltaic cell 5 concerned and the other insulation element 12 of the adjacent photovoltaic cell 5 are placed between this photovoltaic cell 5 and the adjacent photovoltaic cell 5. In other words, in the stack 3, the photovoltaic cells 5 are arranged one after another with positioning an insulation element 10 of a photovoltaic cell 5 and another insulation element 12 of an adjacent photovoltaic cell between two adjacent photovoltaic cells 5.

In other words still, this arrangement is implemented in such a way that the front face 5A of the photovoltaic cell 5 provided with the insulation element 10 is positioned at a distance from the rear face 5B of the adjacent photovoltaic cell 5 provided with the other insulation element 12. For the record, the photovoltaic cells 5 considered in this third embodiment all have the same configuration with an insulation element 10 formed on the front face 5A and another insulation element 12 formed on the rear face 5B. The faces of the photovoltaic cells 5 are therefore not in contact with each other when they are stacked. This makes it possible especially to avoid degrading the metallisation elements, and therefore the electrical performance of the photovoltaic cells.

In this stacking step, as represented in FIG. 6, the insulation element 10 of one photovoltaic cell 5 and the other insulation element 12 of another adjacent photovoltaic cell 5 are therefore positioned in direct contact.

In addition to the advantages set forth for the first embodiment, the configuration of the third embodiment is particularly advantageous because it makes it possible to limit the support points on the photovoltaic cells during stacking. The barrier effect to the penetration of reactive passivation species is also enhanced.

FIGS. 7 and 8 correspond to a fourth example implementation of the passivation method in accordance with the invention.

The passivation method according to this fourth embodiment corresponds, as it were, to a combination of the first and second embodiments previously described. Only the specific features relating to this fourth embodiment are described hereinafter.

After the step of supplying the plurality of photovoltaic cells 5 and before the stacking step, the passivation method according to this fourth example comprises a step of forming an insulation element 10C according to the first example. This forming element 10C is formed on one of the faces 5A, 5B of each photovoltaic cell 5. Here, the insulation element 10C is formed on the front face 5A of each photovoltaic cell 5 (FIGS. 7 and 8).

It also comprises a step of forming a “double” insulation element 10A, 10B according to the second example previously described. This “double” insulation element 10A, 10B comprises an external insulation element 10A (corresponding to the insulation element 10 of the second embodiment previously described) and an internal insulation element 10B (corresponding to the other insulation element 15 of the second embodiment).

As is visible in FIGS. 7 and 8, the external insulation element 10A and the internal insulation element 10B are formed on the face opposite to the face provided with the insulation element 10C. Here, the external insulation element 10A and the internal insulation element 10B are thus formed on the rear face 5B of the photovoltaic cell 5.

In other words, in this fourth embodiment, the photovoltaic cell 5 comprises, on one of its faces, the insulation element 10C and, on the other of its faces, the external insulation element 10A and the internal insulation element 10B.

The specificity of this fourth example implementation of the passivation method lies in the positioning of the insulation element 10C with respect to the external insulation element 10A and the internal insulation element 10B.

As described for the second embodiment previously introduced, the external insulation element 10A and the internal insulation element 10B are formed at a distance from each other. A gap is therefore defined between the external insulation element 10A and the internal insulation element 10B.

In this fourth example, advantageously, the insulation element 10C is formed opposite the gap defined between the external insulation element 10A and the internal insulation element 10B. This positioning then makes it possible, during the stacking step described hereinafter, to position the insulation element 10C of a photovoltaic cell 5 between the external insulation element 10A and the internal insulation element 10B of the adjacent photovoltaic cell 5.

In practice, on the rear face 5B of the photovoltaic cell 5, the external insulation element 10A is formed in proximity to the peripheral edge 5C. More particularly, it is formed at a distance of less than 50 μm from the peripheral edge 5C (thus from the edge of the front face 5A of the photovoltaic cell 5).

The internal insulation element 10B extends, at a distance from the external insulation element 10A, in parallel to this external insulation element 10A. The distance d between the external insulation element 10A and the internal insulation element 10B is less than 100 μm. Preferably, this distance d is less than 50 μm.

For example, the internal insulation element 10B is formed at a distance from the external insulation element 10A in the order of the width of the external insulation element 10A.

For a width of the external insulation element 10A in the order of 50 μm, the internal insulation element 10B is therefore formed at a distance of less than 150 μm from the peripheral edge 5C (hence from the edge of the rear face 5B of the photovoltaic cell 5).

On the front face 5A of the photovoltaic cell 5, the insulation element 10C is, for its part, formed at a predetermined distance from the peripheral edge 5C of the photovoltaic cell 5 so that it is positioned facing the gap defined between the external insulation element 10A and the internal insulation element 10B. With the examples of positioning distances previously provided for the external insulation element 10A and the internal insulation element 10B, the insulation element 10 is here formed at a distance of between 100 and 150 μm from the peripheral edge 5C (thus from the edge of the front face 5A of the photovoltaic cell 5).

For the rest, the insulation element 10C, the external insulation element 10A and the internal insulation element 10B have the same characteristics as those previously described in the first and second examples of implementation of the passivation method (in particular relating to the width and height dimensions, the shape of the transverse cross-section, materials used).

It is to be noted that the materials used to form the insulation element 10C, the external insulation element 10A and the internal insulation element 10B may be different.

Furthermore, in this fourth mode of implementation of the passivation method, there is no order of formation between the insulation element 10C, the external insulation element 10A and the internal insulation element 10B. In particular, they may be formed simultaneously in order to simplify manufacture.

Thus, in this fourth embodiment (FIGS. 7 and 8), prior to the stacking step, each photovoltaic cell 5 of the plurality of photovoltaic cells is provided, on the one hand, with an insulation element 10C on one of the faces (here the front face 5A) and, on the other hand, with the external insulation element 10A and the internal insulation element 10B, both formed on the other of the faces (here the rear face 5B).

The passivation method then continues with the step of stacking the plurality of photovoltaic cells 5 each provided with the insulation element 10C, the external insulation element 10A and the internal insulation element 10B (a stack 4, visible in FIG. 8, of photovoltaic cells, insulation elements 10C, external insulation elements 10A and internal insulation elements 10B is thus formed).

This stack 4 is here implemented vertically: the photovoltaic cells 5 are then superimposed on one another (as is represented in FIG. 8). Alternatively, the stack may be made horizontally. In this case, the photovoltaic cells are positioned one after the other.

Advantageously according to the invention, each photovoltaic cell 5 is positioned so that the insulation element 10C of one photovoltaic cell and the external insulation element 10A and the internal insulation element 10B of the adjacent photovoltaic cell 5 are placed between this photovoltaic cell 5 and the adjacent photovoltaic cell 5. In other words, in the stack 4, the photovoltaic cells 5 are arranged one after another with positioning an insulation element 10 of one photovoltaic cell 5 and an external insulation element 10A and an internal insulation element 10B of an adjacent photovoltaic cell between two adjacent photovoltaic cells 5.

In other words still, this arrangement is implemented in such a way that the front face 5A of the photovoltaic cell 5 provided with the insulation element 10 is positioned at a distance from the rear face 5B of the adjacent photovoltaic cell 5 provided with the external insulation element 10A and the internal insulation element 10B. For the record, the photovoltaic cells 5 considered in this fourth embodiment all have the same configuration with an insulation element 10C formed on the front face 5A and an external insulation element 10A and an internal insulation element 10B formed on the rear face 5B. The faces of the photovoltaic cells 5 are therefore not in contact with each other when they are stacked. This makes it possible especially to avoid degrading the metallisation elements, and therefore electrical performance of the photovoltaic cells.

Advantageously here, and by virtue of the arrangement of the insulation element 10C, the external insulation element 10A and the internal insulation element 10B, the stacking of the photovoltaic cells 5 is implemented in such a way that the insulation element 10C of one photovoltaic cell 5 is positioned between the external insulation element 10A and the internal insulation element 10B of the adjacent photovoltaic cell 5. This configuration is visible in FIG. 8.

In addition to the advantages set forth for the first and second embodiments, the configuration of the fourth embodiment is particularly advantageous because, by virtue of the arrangement, alternately and in a juxtaposed manner, of the insulation element 10C, the external insulation element 10A and the internal insulation element 10B, it makes it possible to enhance the penetration barrier effect of the passivation species used for deposition. The insulation element 10C, the external insulation element 10A and the internal insulation element 10B therefore form a triple barrier enabling the front face 5A and the rear face 5B of each photovoltaic cell 5 to be insulated from outside the stack 4. This further ensures that only the peripheral edge 5C of the photovoltaic cells 5 is exposed to the passivation species for deposition of the passivation layer (the other parts of the photovoltaic cells 5 being insulated by virtue of the presence of the insulation element 10C, the external insulation element 10A and the internal insulation element 10B between each photovoltaic cell 5, which form a triple barrier to the passivation species used).

In addition, positioning the insulation element 10C between the external insulation element 10A and the internal insulation element 10B makes it possible to ensure that the photovoltaic cells 5 are properly aligned when they are stacked (also ensuring formation of the passivation layer on the peripheral edges 5C of the photovoltaic cells 5 stacked).

FIGS. 9 and 10 correspond to a fifth example implementation of the passivation method in accordance with the invention.

The passivation method according to this fifth example comprises the same steps of supplying the plurality of photovoltaic cells, forming the insulation elements, stacking and depositing a passivation layer as the second embodiment previously described. Therefore, only the differences with respect to this second exemplary embodiment are described in detail hereinafter.

Thus, on the basis of what is described for the second exemplary embodiment, one of the faces (for example the front face) of each photovoltaic cell 5 is provided with an external insulation element 10A (corresponding to the insulation element 10 of the second exemplary embodiment) and an internal insulation element 10B (corresponding to the other insulation element 15 of the second exemplary embodiment).

In this fifth embodiment of the passivation method, prior to the stacking step, the passivation method comprises a step of forming a further external insulation element 12A and a further internal insulation element 12B (on each photovoltaic cell 5 of the plurality of photovoltaic cells).

As is visible in FIGS. 9 and 10, the other external insulation element 12A and the other internal insulation element 12B are formed on the face opposite to that on which the external insulation element 10A and the internal insulation element 10B (described according to the second example embodiment) are formed. Here, the other external insulation element 12A and the other internal insulation element 12B are therefore formed on the rear face 5B of the photovoltaic cell. Alternatively, if the external insulation element and the internal insulation element are formed on the rear face of the photovoltaic cell, the other external insulation element and the other internal insulation element are of course formed, in the same manner, on the front face of the photovoltaic cell.

The other external insulation element 12A and the other internal insulation element 12B are formed, on the rear face 5B of the photovoltaic cell 5, in the same way as the external insulation element 10A and the internal insulation element 10B are formed on the front face 5A.

The specificity of this fifth example implementation of the passivation method lies in positioning the other external insulation element 12A and the other internal insulation element 12B (with respect to the external insulation element 10A and the internal insulation element 10B).

As described for the second embodiment previously introduced, the other external insulation element 12A and the other internal insulation element 12B are formed at a distance from each other. A gap is therefore defined between the other external insulation element 10A and the other internal insulation element 10B.

In this fifth example, advantageously, the other external insulation element 12A is formed facing the gap defined between the external insulation element 10A and the internal insulation element 10B. This positioning then makes it possible, during the stacking step described hereinafter, to position the other external insulation element 12A of a photovoltaic cell 5 between the external insulation element 10A and the internal insulation element 10B of the adjacent photovoltaic cell 5.

In practice, on the front face 5A of the photovoltaic cell 5, the external insulation element 10A is formed in proximity to the peripheral edge 5C. More particularly, it is formed at a distance of less than 50 μm from the peripheral edge 5C (thus from the edge of the front face 5A of the photovoltaic cell 5).

The internal insulation element 10B extends, at a distance from the external insulation element 10A, in parallel to this external insulation element 10A. The distance d₁ between the external insulation element 10A and the internal insulation element 10B is less than 100 μm. Preferably, this distance d₁ is less than 50 μm.

For example, the internal insulation element 10B is formed at a distance from the external insulation element 10A in the order of the width of the external insulation element 10A.

For a width of the external insulation element 10A in the order of 50 μm, the internal insulation element 10B is therefore formed at a distance of less than 150 μm from the peripheral edge 5C (thus from the edge of the front face 5A of the photovoltaic cell 5).

On the rear face 5B of the photovoltaic cell 5, the external insulation element 12A, for its part, is formed at a predetermined distance from the peripheral edge 5C of the photovoltaic cell 5 so that it is positioned facing the gap defined between the external insulation element 10A and the internal insulation element 10B (formed on the front face 5A of the photovoltaic cell 5). With the examples of positioning distances previously provided for the external insulation element 10A and the internal insulation element 10B, the other external insulation element 12A is here at a distance of between 100 and 150 μm from the peripheral edge 5C (thus from the edge of the rear face 5B of the photovoltaic cell 5).

The other internal insulation element 12B is formed, with respect to the other external insulation element 12A, in the same way as the internal insulation element 10B is formed with respect to the external insulation element 10A.

In particular, the other internal insulation element 12B is formed at a distance from the other external insulation element 12A (thus also at a distance from the peripheral edge 5C of the photovoltaic cell 5). For example, the distance d₂ between the other external insulation element 12A and the other internal insulation element 12B is less than 100 μm. Preferably, this distance d₂ is less than 50 μm.

For example, the other internal insulation element 12B is formed at a distance from the other external insulation element 12A in the order of the width of the external insulation element 10A.

The distance between the external insulation element 10A and the internal insulation element 10B, on the one hand, and the other external insulation element 12A and the other internal insulation element 12B, on the other hand, is for example identical. Alternatively, it may of course be different.

For the rest, the external insulation element 10A, the internal insulation element 10B, the other external insulation element 12A and the other internal insulation element 12B have the same characteristics as those previously described in the second example implementation of the passivation method (in particular as regards the width and height dimensions, the shape of the transverse cross-section and the materials used).

It is to be noted that the materials used to form the external insulation element 10A, the internal insulation element 10B, the other external insulation element 12A and the other internal insulation element 12B may be different.

Furthermore, in this fifth mode of implementation of the passivation method, there is no order of formation between the external insulation element 10A, the internal insulation element 10B, the other external insulation element 12A and the other internal insulation element 12B. In particular, they can be formed simultaneously, on the one hand, on the front face and, on the other hand, on the rear face, in order to simplify manufacture. There is no order of formation between the insulation elements on the front face and the insulation elements on the rear face.

Thus, in this fifth embodiment (FIGS. 9 and 10), before the stacking step, each photovoltaic cell 5 of the plurality of photovoltaic cells is provided, on the one hand, with an external insulation element 10A and an internal insulation element 10B on one of the faces (here the front face 5A) and, on the other hand, the other external insulation element 12A and the other internal insulation element 12B, both formed on the other of the faces (here the rear face 5B) of the photovoltaic cell 5.

The passivation method then continues with the step of stacking the plurality of photovoltaic cells 5 each provided with the external insulation element 10A, the internal insulation element 10B, the other external insulation element 12A and the other insulation element 12B (a stack 6, visible in FIG. 10, of photovoltaic cells, external insulation elements 10A, internal insulation elements 10B, other external insulation elements 12A and other internal insulation elements 12B is thus formed).

This stack 6 is here implemented vertically: the photovoltaic cells 5 are then superimposed on one another (as is represented in FIG. 10). Alternatively, the stack may be made horizontally. In this case, the photovoltaic cells are positioned one after the other.

Advantageously according to the invention, as is represented in FIG. 10, each photovoltaic cell 5 is positioned so that, on the one hand, the external insulation element 10A and the internal insulation element 10B of one photovoltaic cell and, on the other hand, the other external insulation element 12A and the other internal insulation element 12B of the adjacent photovoltaic cell 5 are placed between this photovoltaic cell 5 and the adjacent photovoltaic cell 5. In other words, in the stack 6, the photovoltaic cells 5 are arranged one after another with positioning, on the one hand, an external insulation element 10A and an internal insulation element 10B of one photovoltaic cell and, on the other hand, another external insulation element 12A and another internal insulation element 12B of an adjacent photovoltaic cell between two adjacent photovoltaic cells 5.

In other words still, this arrangement is implemented such that the front face 5A of the photovoltaic cell 5 provided with the external insulation element 10A and the internal insulation element 10B is positioned at a distance from the rear face 5B of the adjacent photovoltaic cell 5 provided with the other external insulation element 12A and the other internal insulation element 12B.

For the record, the photovoltaic cells 5 considered in this fifth embodiment all have the same configuration with, on the one hand, an external insulation element 10A and an internal insulation element 10B formed on the front face, and, on the other hand, another external insulation element 12A and another internal insulation element 12B formed on the rear face 5B.

The faces of the photovoltaic cells 5 are therefore not in contact with each other when they are stacked. This makes it possible especially to avoid degrading metallisation elements, and hence electrical performance of the photovoltaic cells.

Advantageously here, and by virtue of the arrangement of the external insulation element 10A, the internal insulation element 10B, the other external insulation element 12A and the other internal insulation element 12B, the stacking of the photovoltaic cells 5 is implemented in such a way that the other external insulation element 12A is positioned between the external insulation element 10A and the internal insulation element 10B of the adjacent photovoltaic cell 5. This configuration is visible in FIG. 10. According to this arrangement, the internal insulation element 10B is positioned between the other external insulation element 12A and the other internal insulation element 12B.

In addition to the advantages set forth for the second embodiment, the configuration of the fifth mode of implementation is particularly advantageous because, by virtue of the arrangement, alternately and in a juxtaposed manner, of the external insulation element 10A, the internal insulation element 10B, the other external insulation element 12A and the other internal insulation element 12B, it makes it possible to enhance penetration barrier effect of the passivation species used for deposition. The external insulation element 10A, the internal insulation element 10B, the other external insulation element 12A and the other internal insulation element 12B therefore form a quadruple barrier enabling the front face 5A and the rear face 5B of each photovoltaic cell 5 to be insulated from outside the stack 6. This further ensures that only the peripheral edge 5C of the photovoltaic cells 5 is exposed to the passivation species for the deposition of the passivation layer (the other parts of the photovoltaic cells 5 being insulated by virtue of the presence of the external insulation element 10A, the internal insulation element 10B, the other external insulation element 12A and the other internal insulation element 12B between each photovoltaic cell 5, which form a quadruple barrier to the passivation species used).

Furthermore, positioning the external insulation element 10A, the internal insulation element 10B, the other external insulation element 12A and the other internal insulation element 12B, in a successive and juxtaposed manner, makes it possible to ensure that the photovoltaic cells 5 are properly aligned when they are stacked (also ensuring formation of the passivation layer on the peripheral edges 5C of the stacked photovoltaic cells 5).

The present invention is described for sub-cells but can also be implemented with full-size photovoltaic cells. In particular, for advanced cell technologies such as heterojunction (HET) cells, it may be useful to improve the existing passivation of the cell edges by forming a new passivation layer.

1. A method for passivating photovoltaic cells comprising:
providing a plurality of photovoltaic cells, each photovoltaic cell comprising a front face, to be exposed to incident radiation, a rear face opposite to the front face and a peripheral edge connecting the front face and the rear face,
on each photovoltaic cell of the plurality of photovoltaic cells, forming a first insulation element shaped along the perimeter of the photovoltaic cell concerned, the first insulation element being formed on the front face or on the rear face of the photovoltaic cell concerned,
stacking the plurality of photovoltaic cells, the first insulation element of each photovoltaic cell being positioned between the photovoltaic cell concerned and an adjacent photovoltaic cell in such a way that the face of the photovoltaic cell provided with the first insulation element is positioned at a distance from the face facing the adjacent photovoltaic cell, and
depositing a passivation layer onto the peripheral edge of the photovoltaic cells of the plurality of photovoltaic cells by injecting at least one passivation species, the first insulation element forming a penetration barrier to the passivation species so that the passivation layer covers the peripheral edge of each photovoltaic cell.

2. The passivation method according to claim 1, wherein, for each photovoltaic cell of the plurality of photovoltaic cells, the first insulation element is formed, on one of the front face or the rear face, at a distance, from the peripheral edge, of less than 50 micrometres.

3. The passivation method according to claim 1, wherein the first insulation element has a width of less than 100 micrometres.

4. The passivation method according to claim 1, wherein the first insulation element has a width of between 30 and 60 micrometres.

5. The passivation method according to claim 1, wherein, each photovoltaic cell having, on at least one of the front face and the rear face, at least one metallisation element, the first insulation element has a height greater than or equal to the height of the metallisation element.

6. The passivation method according to claim 1, wherein the first insulation element is formed of an electrically conductive metal material.

7. The passivation method according to claim 6, wherein the first insulation element is formed by screen printing.

8. The passivation method according to claim 1, wherein the first insulation element is formed of a polymeric material.

9. The passivation method according to claim 1, wherein, during the stacking, the photovoltaic cells are positioned such that the first insulation element formed is in direct contact with one of the faces of the adjacent photovoltaic cell.

10. The passivation method according to claim 1, comprising, for each photovoltaic cell, forming a second insulation element around the perimeter of the photovoltaic cell concerned, the second insulation element being formed on the same face as the first insulation element, in parallel with the first insulation element.

11. The passivation method according to claim 10, wherein the second insulation element is formed at a distance from the first insulation element of less than 50 micrometres.

12. The passivation method according to claim 1, comprising, for each photovoltaic cell, forming a third insulation element shaped along the perimeter of the photovoltaic cell concerned, the third insulation element being formed on the face opposite to the face provided with the first insulation element.

13. The passivation method according to claim 12, wherein the second insulation element is formed at a distance from the first insulation element of less than 50 micrometres and wherein, during the stacking, the photovoltaic cells are positioned so that the third insulation element of a photovoltaic cell is placed between the first insulation element and the second insulation element of the adjacent photovoltaic cell, the third insulation element being in direct contact with the face of the adjacent photovoltaic cell on which the first insulation element and the second insulation element are formed.

14. The passivation method according to claim 1, comprising, for each photovoltaic cell, forming a fourth insulation element shaped along the perimeter of the photovoltaic cell concerned, the fourth insulation element being formed on the face opposite to the face provided with the first insulation element, the fourth insulation element being formed facing the first insulation element.

15. The passivation method according to claim 14 wherein, during the stacking, the photovoltaic cells are positioned such that the first insulation element of one photovoltaic cell is in contact with the fourth insulation element of the adjacent photovoltaic cell.
